(19) United States
(12) Patent Application Publication
(10) Pub. No.: US 2026/0213719 A1
(43) Pub. Date: Jul. 23, 2026

(54) ADJUSTING VOLUME OF AUDIO PLAYBACK BASED ON A DETECTED USER SLEEPING

(71) Applicant: Motorola Mobility LLC, Chicago, IL (US)

(72) Inventors: Amit Kumar Agrawal, Bangalore (IN); Nakul Patel, Bangalore (IN); Krishnan Raghavan, Bangalore (IN)

(73) Assignee: Motorola Mobility LLC, Chicago, IL (US)

(21) Appl. No.: 19/033,353

(22) Filed: Jan. 21, 2025

(51) Int. Cl. H03G 3/20; H04R 3/00

(52) U.S. Cl. CPC H03G 3/20; H04R 3/00; H04R 2430/01

(57) ABSTRACT

In aspects of adjusting volume of audio playback based on a detected user sleeping, a first computing device implements a volume manager that determines whether a user of the first computing device is sleeping. The volume manager detects audio playback that is output from speakers of a second computing device located within a threshold proximity to the first computing device. The volume manager then outputs a trigger to cause the second computing device to adjust a volume of the audio playback based on a determination that the user of the first computing device is sleeping.

### BACKGROUND

Computing devices are capable of outputting multiple types of audio playback using speaker systems incorporated into the computing devices. For example, the audio playback may include music, video audio, podcasts, recordings, game audio, or any other type of audio. However, the audio playback results in challenges, such as the audio playback interrupting a nearby person sleeping in some examples.

### BRIEF DESCRIPTION OF THE DRAWINGS

Implementations of techniques for adjusting volume of audio playback based on a detected user sleeping are described with reference to the following Figures. The same numbers may be used throughout to reference like features and components shown in the Figures.

FIG. 1 illustrates an example system for adjusting volume of audio playback based on a detected user sleeping in accordance with one or more implementations as described herein.

FIG. 2 further illustrates an example of adjusting volume of audio playback based on a detected user sleeping, including determining a status of a user of a first computing device sleeping, in accordance with one or more implementations as described herein.

FIG. 3 further illustrates an example of adjusting volume of audio playback based on a detected user sleeping, including sending a trigger to a second computing device to adjust a volume of audio playback, in accordance with one or more implementations as described herein.

FIG. 4 further illustrates an example of adjusting volume of audio playback based on a detected user sleeping, including sending a trigger to a second computing device to turn off autoplay, in accordance with one or more implementations as described herein.

FIG. 5 further illustrates an example of adjusting volume of audio playback based on a detected user sleeping, including determining whether a user of the first computing device is predicted to be sleeping, in accordance with one or more implementations as described herein.

FIG. 6 further illustrates an example of adjusting volume of audio playback based on a detected user sleeping, including sending a trigger to a second computing device to adjust a volume of audio playback in response to determining that the user of the first computing device is predicted to be sleeping, in accordance with one or more implementations as described herein.

FIG. 7 further illustrates an example of adjusting volume of audio playback based on a detected user sleeping, including determining that the user of the first computing device is not predicted to be sleeping, in accordance with one or more implementations as described herein.

FIG. 8 is a flowchart illustrating an example of adjusting volume of audio playback based on a detected user sleeping in accordance with one or more implementations as described herein.

FIG. 9 illustrates an example method for adjusting volume of audio playback based on a detected user sleeping in accordance with one or more implementations of the techniques described herein.

FIG. 10 illustrates an example method for adjusting volume of audio playback based on a detected user sleeping in accordance with one or more implementations of the techniques described herein.

FIG. 11 illustrates various components of an example device that may be used to implement the techniques for adjusting volume of audio playback based on a detected user sleeping in accordance with one or more implementations as described herein.

### DETAILED DESCRIPTION

Implementations of the techniques for adjusting volume of audio playback based on a detected user sleeping may be implemented as described herein. A first computing device and a second computing device, such as any type of wearable computing device, mobile phone, or other computing device, may be configured to perform the techniques for adjusting volume of audio playback based on a detected user sleeping. In one or more implementations, a volume manager, housed in the first computing device, the second computing device, a central computing device, or a network-based cloud accessible to the first computing device and the second computing device, can be used to implement aspects of the techniques described herein.

Computing devices may facilitate a variety of health monitoring functions. For example, wearable computing devices, such as smart watches and smart rings, are capable of measuring heart rate, blood pressure, and oxygen levels. Specifically, measuring data related to sleep has become a large focus to help users maximize rest and recovery. For example, computing devices are also configured to determine when a user is sleeping in order to provide additional health-related insights to the user.

Computing devices are also capable of outputting multiple types of audio playback using speaker systems incorporated into the computing devices. For example, the audio playback may include music, video audio, podcasts, recordings, game audio, or any other type of audio. However, challenges arise when a user of a first computing device is sleeping, while a second computing device located within a close proximity to the first computing device is engaged in outputting the audio playback. For instance, the user of the first computing device is trying to sleep, but is abruptly waken by audio from a video played by the second computing device located in the same room by another user. The audio from the video, for instance, may be unintentionally played from a pop-up ad or a queued video, but still has the effect of interfering with the sleep of the user of the first computing device.

Techniques and systems are described for adjusting volume of audio playback based on a detected user sleeping that overcome these limitations. To begin, the volume manager determines that a user of the first computing device is sleeping. For example, the volume manager may receive sleep data collected or received by the first computing device, including metrics that may be used to determine whether the user of the first computing device is sleeping, such as environmental data, medical data, or behavioral data. Examples of the environmental data include information collected by a smart home environment, including data from thermostats, lights, noise sensors, ambient sound, smart beds, cameras, and/or motion sensors that the volume manager may use to determine whether the user is asleep. Examples of the medical data include data information related to physical movement, breathing patterns, heart rate, brain activity, and body temperature that the volume manager may leverage to determine whether the user is asleep. Examples of the behavioral data include information related to pre-set schedules, inferred schedules based on historical data, sleep diaries, phone usage patterns, and calendar routines that the user may use to determine whether the user is asleep, for instance by leveraging a machine learning model trained to predict whether the user of the first computing device is expected to be asleep based on historical data.

Additionally, the volume manager may determine that a status of media playing on the second computing device is active, indicating that audio output associated with music, video audio, podcasts, recordings, game audio, or any other type of audio is output for consumption. The first computing device in this example is determined to have higher priority than the second computing device because the user of the first computing device is sleeping, while the second computing device is engaged in consuming media.

In some example implementations, the volume manager may also determine that the first computing device and the second computing device are physically located within a close proximity of each other, which may be defined as a threshold distance or presence in the same room. To do this, the volume manager receives location data from a location device of the first computing device and the second computing device and compares the location data to determine whether the first computing device and the second computing device are located within the proximity of each other.

Because the first computing device and the second computing device are within the threshold distance of each other, the audio playback may prevent the user of the first computing device from sleeping. For this reason, if the volume manager determines that the user of the first computing device is sleeping, the volume manager initiates a volume adjustment, such as muting speakers of the second computing device, to prevent the audio playback from the second computing device from preventing the user of the first computing device from sleeping. Additionally, the volume manager may cause display of a message on the second computing device alerting the user of the second computing device that the user of the first computing device is sleeping and therefore the speakers of the second computing device have been muted. In some example implementations, the volume manager also pauses autoplay on the second computing device to prevent further unexpected interruptions.

The volume manager continues to monitor indicators that determine whether the user of the first computing device is asleep. For example, after determining that the user of the first computing device has awaken and is no longer asleep, the volume manager may end the volume adjustment on the second computing device so that the user of the second computing device is no longer restricted from listening to the audio playback.

The described techniques for adjusting volume of audio playback based on a detected user sleeping overcome the limitations of conventional systems. For example, determining that a user of a first computing device is sleeping and that audio playback is output from speakers of a nearby second computing device is used to determine whether the audio playback is interrupting the user of the first computing device sleeping. Additionally, sending a trigger to the second computing device to adjust a volume of the audio playback, such as muting the audio playback, reduces interruptions to the user of the first computing device sleeping. This alleviates user frustration that may stem from unwanted audio playback interfering with sleep.

While features and concepts of the described techniques for adjusting volume of audio playback based on a detected user sleeping is implemented in any number of different devices, systems, environments, and/or configurations, implementations of the techniques for adjusting volume of audio playback based on a detected user sleeping are described in the context of the following example devices, systems, and methods.

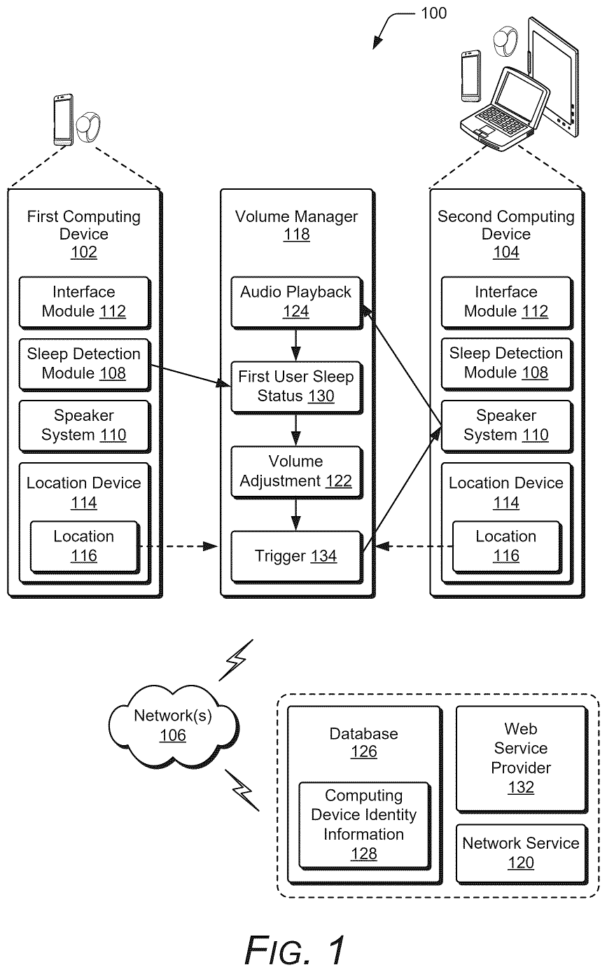

FIG. 1 illustrates an example system 100 for adjusting volume of audio playback based on a detected user sleeping. The system 100 includes a first computing device 102, a second computing device 104, and a communication network 106. Examples of the first computing device 102 and the second computing device 104 include at least one of any type of a wireless device, mobile device, mobile phone, flip phone, client device, companion device, tablet, computing device, communication device, entertainment device, gaming device, media playback device, any other type of computing and/or electronic device. In this example implementation, the first computing device 102 may be a wearable computing device, such as a smart watch, smart ring, or other wearable device.

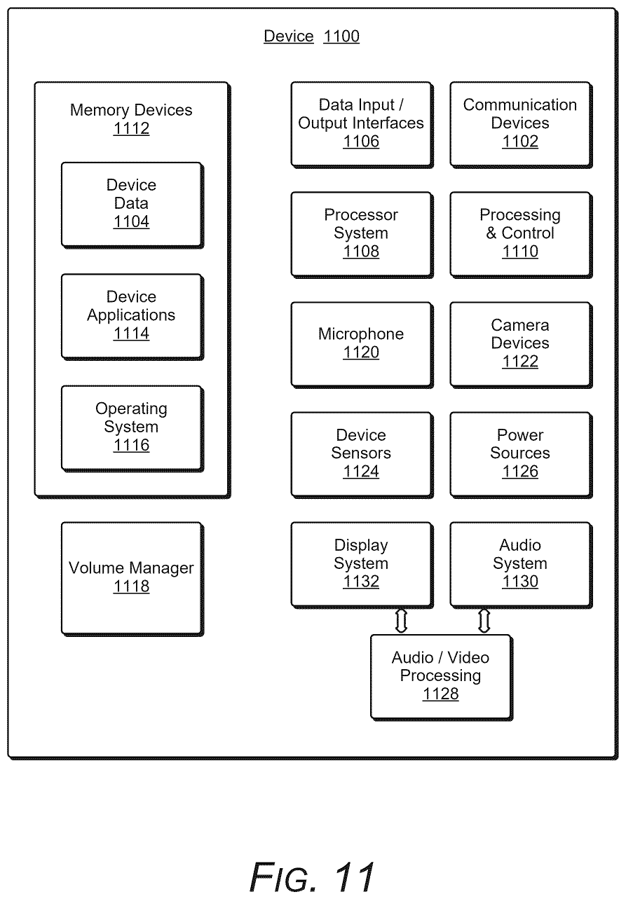

The first computing device 102 and the second computing device 104 can be implemented with various components, such as a processor system and memory, as well as any number and combination of different components as further described with reference to the example device shown in FIG. 11. In implementations, the first computing device 102 and the second computing device 104 are equipped with a sleep detection module 108, which may analyze sleep data to make determinations related to whether a user is sleeping. The sleep data, for instance, may be related to environmental data, medical data, and/or behavioral data, which may be collected by or received by the sleep detection module 108. Examples of the environmental data include information related to thermostats, lights, noise sensors, ambient sound, smart beds, cameras, and/or motion sensors. Examples of the medical data include data information related to physical movement, breathing patterns, heart rate, brain activity, thermal readings, and body temperature. Examples of the behavioral data include information related to pre-set schedules, inferred schedules based on historical data, sleep diaries, phone usage patterns, and calendar routines.

The first computing device 102 and the second computing device 104 are also equipped with a speaker system 110 to output audio playback. For example, the audio playback may include video audio, call audio, music, or other audio from any type of media. The audio playback, for instance, may be streamed or accessed by the first computing device 102

In some implementations, the devices, applications, modules, servers, and/or services described herein communicate via the communication network 106, such as for data communication with the first computing device 102 and the second computing device 104. The interface module 112 includes a wired and/or a wireless network. The interface module 112 is implemented using any type of network topology and/or communication protocol and is represented or otherwise implemented as a combination of two or more networks, to include IP based networks, cellular networks, and/or the Internet. The communication network 106 includes mobile operator networks that are managed by a mobile network operator and/or other network operators, such as a communication service provider, mobile phone provider, and/or Internet service provider.

The first computing device 102 and the second computing device 104 include various functionalities that enable the devices to implement different aspects of adjusting volume of audio playback based on a detected user sleeping, as described herein. In one or more examples, an interface module 112 represents functionality (e.g., logic and/or hardware) enabling the first computing device 102 and the second computing device 104 to interconnect and interface with other devices and/or networks, such as the communication network 106. For example, the interface module 112 enables wireless and/or wired connectivity of the first computing device 102 and the second computing device 104.

The first computing device 102 and the second computing device 104 can include and implement an application, such as any type of messaging application, email application, video communication application, cellular communication application, music/audio application, gaming application, media application, social platform applications, and/or any other of the many possible types of various device applications. Many of the device applications have an associated application user interface that is generated and displayed for user interaction and viewing, such as on a display screen of the first computing device 102 or the second computing device 104. Generally, an application user interface, or any other type of video, image, graphic, and the like is digital image content that is displayable on the display screen of the first computing device 102 and the second computing device 104. The application may be accessible to the first computing device 102 and the second computing device 104 from an application service provider via the communication network 106.

In implementations, the first computing device 102 and the second computing device 104 may include any type of location device 114, such as a GPS transceiver or other type of geo-location device, to determine a location 116 of the first computing device 102 and the second computing device 104. Notably, any of the devices described herein, to include components, modules, services, computing devices, camera devices, and/or the tracking tags, can share the GPS data between any of the devices, whether they are GPS-hardware enabled or not. Additionally or alternatively, the first computing device 102 and the second computing device 104 can also include various radios for wireless communication in the environment, such as a UWB radio, Bluetooth radio, or a Wi-Fi radio implemented for wireless communications with the other devices in the environment.

In the example system 100 for adjusting volume of audio playback based on a detected user sleeping, the first computing device 102 and/or the second computing device 104 implements a volume manager 118. For example, the volume manager 118 can represent functionality that resides on the first computing device 102 and/or the second computing device 104. Alternatively or additionally, the volume manager 118 may be implemented using a network service 120, such as a cloud-based service, in communication with the first computing device 102 and the second computing device 104 via the communication network 106. Alternatively or additionally, the volume manager 118 is implemented in an external device in communication with the first computing device 102 and the second computing device 104 via the communication network 106. As shown in this example, the volume manager 118 represents functionality (e.g., logic, software, and/or hardware) enabling aspects of the described techniques for adjusting volume of audio playback based on a detected user sleeping. The volume manager 118 can be implemented as computer instructions stored on computer-readable storage media and can be executed by a processor system of the first computing device 102 and/or the second computing device 104. Alternatively, or in addition, the volume manager 118 can be implemented at least partially in hardware of the device.

In one or more implementations, the volume manager 118 includes independent processing, memory, and/or logic components functioning as a computing and/or electronic device integrated with the first computing device 102 and/or the second computing device 104. Alternatively, or in addition, the volume manager 118 can be implemented in software, in hardware, or as a combination of software and hardware components. In this example, the volume manager 118 is implemented as a software application or module, such as executable software instructions (e.g., computer-executable instructions) that are executable with a processor system of the first computing device 102 and/or the second computing device 104 to implement the techniques and features described herein. As a software application or module, the volume manager 118 can be stored on computer-readable storage memory (e.g., memory of a device), or in any other suitable memory device or electronic data storage implemented with the controller. Alternatively or in addition, the volume manager 118 is implemented in firmware and/or at least partially in computer hardware. For example, at least part of the volume manager 118 is executable by a computer processor, and/or at least part of the content manager is implemented in logic circuitry.

In this example system 100, the volume manager 118 determines a volume adjustment 122 for the speaker system 110 of the second computing device 104 to lower a volume of or mute the audio playback 124. Therefore, the audio playback 124 avoids interfering with a user of the first computing device 102 sleeping.

To do this, the volume manager 118 determines that the first computing device 102 and the second computing device 104 are physically located within a close proximity of each other (i.e., are co-located), such as within a threshold distance of each other. To do this, the volume manager 118 leverages the location device 114 to determine the location 116 of the first computing device 102 and the second computing device 104. For example, the location device 114 is a GPS device, and the volume manager 118 determines the location 116 based on GPS data. Additionally or alternatively, the location device 114 involves a UWB tag incorporated in the first computing device 102 and the second computing device 104, and the volume manager 118 determines the first computing device 102 is within the threshold distance by comparing the signal path loss from received signals from the UWB tags. In some implementations, the volume manager 118 accesses a database 126 via the communication network 106 that includes computing device identity information 128. Furthermore, in some example implementations, the proximity is determined based on the first computing device 102 and the second computing device 104 being positioned within the same room or other defined area.

Additionally, in some implementations the volume manager 118 determines whether a sleep status 130 of the user of the first computing device 102 indicates sleeping. For example, the volume manager 118 leverages the sleep detection module 108 to determine that the user of the first computing device 102 is sleeping based on the sleep data, which may include one or more of the environmental data, the medical data, or the behavioral data. In these examples, a determination that the user of the first computing device 102 is sleeping may also cover scenarios in which the user of the first computing device 102 is attempting to sleep or is resting.

For example, if the sleep status 130 determined by the sleep detection module 108 of the first computing device 102 indicates the user of the first computing device 102 is sleeping, then the audio playback 124 from the speaker system 110 of the second computing device 104 would interrupt the user of the first computing device 102 sleeping. The first computing device 102 in this example is determined to have higher priority than the second computing device 104 because the user of the first computing device 102 is sleeping.

The volume manager 118 also determines that audio playback 124 is actively output from the speaker system 110 of the second computing device 104. For example, the audio playback 124 may be video audio, call audio, music, or other audio from any type of audio media output via the speaker system 110. The audio media, for instance, may be streamed or accessed by the first computing device 102 from a web service provider 132 via the communication network 106. The volume manager 118 then determines the volume adjustment 122 for the speaker system 110 of the second computing device 104, which may involve muting the speaker system 110 of the second computing device 104, pausing audio playback 124, and/or pausing auto play on the second computing device 104 for a duration that the user of the first computing device 102 is determined to be sleeping.

To perform the volume adjustment 122, the volume manager 118 sends a trigger 134 to the second computing device 104 to instruct the second computing device 104 to perform the volume adjustment 122. For example, after executing the volume adjustment 122, the volume of the speaker system 110 is muted or turned down, reducing to the user of the first computing device 102 sleeping.

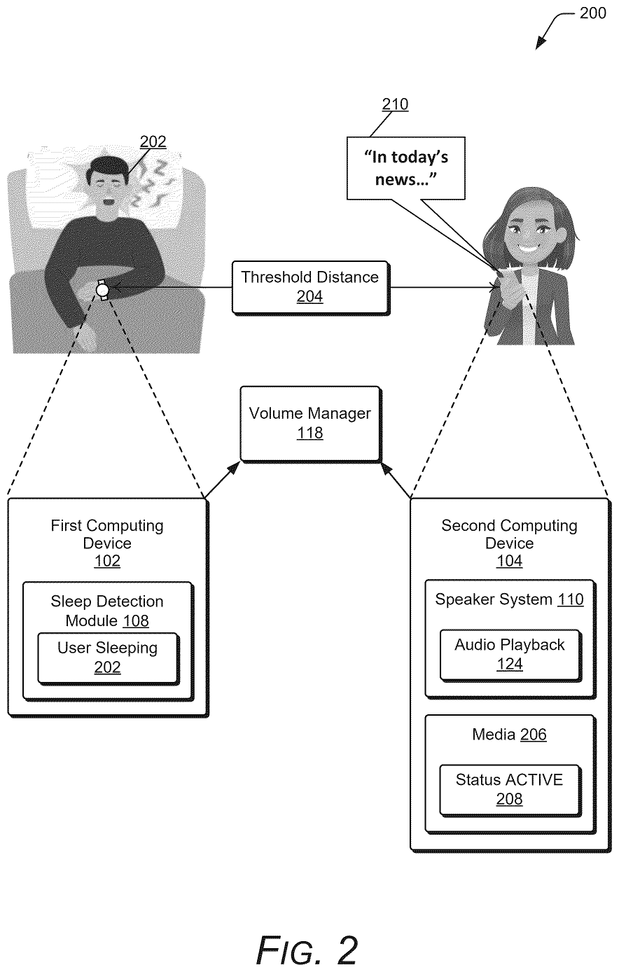

FIG. 2 illustrates an example 200 of adjusting volume of audio playback based on a detected user sleeping, including determining a status of a user of a first computing device sleeping, as described herein. In the example 200, a volume manager 118 configured for adjusting volume of audio playback based on a detected user sleeping may be implemented in a first computing device 102, a second computing device 104, or in another device or network-based cloud that is in communication with the first computing device 102 and the second computing device 104.

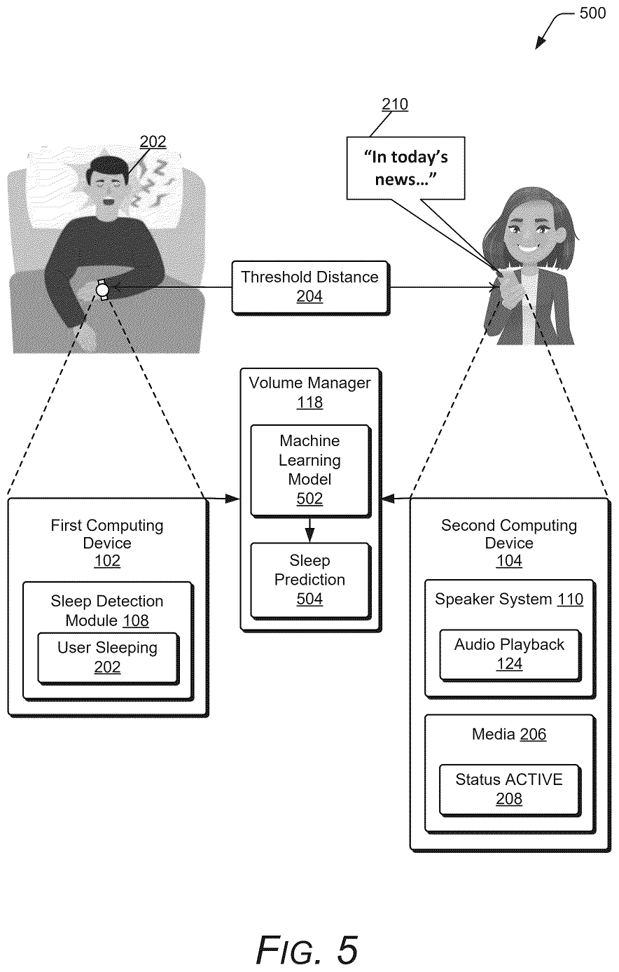

As illustrated in this example, the user of the first computing device 102 is sleeping 202 while wearing or otherwise passively using the first computing device 102. For instance, the first computing device 102 is a smart watch configured to capture sleep data from the user. The volume manager 118 determines, based on the sleep data, that the user of the first computing device 102 is sleeping 202, which is explained in further detail in relation to FIG. 5 below.

In some example implementations, the volume manager 118 may also determine that the first computing device 102 and the second computing device 104 are physically within proximity of each other, such as within a threshold distance 204. To do this, the volume manager 118 receives location data from the location device 114 of the first computing device 102 and the second computing device 104 and compares the location data to determine whether the first computing device 102 and the second computing device 104 are located within the threshold distance 204. For example, the location device 114 is a GPS device, and the volume manager 118 determines the location 116 based on GPS data. Additionally or alternatively, the location device 114 involves a UWB tag incorporated in the first computing device 102 and the second computing device 104, and the volume manager 118 determines the first computing device 102 is within the threshold distance by comparing the signal path loss from received signals from the UWB tags. In some implementations, the volume manager 118 accesses a database 126 via the communication network 106 that includes computing device identity information 128. As illustrated in this example, the volume manager 118 determines that the first computing device 102 and the second computing device 104 are located within the threshold distance 204.

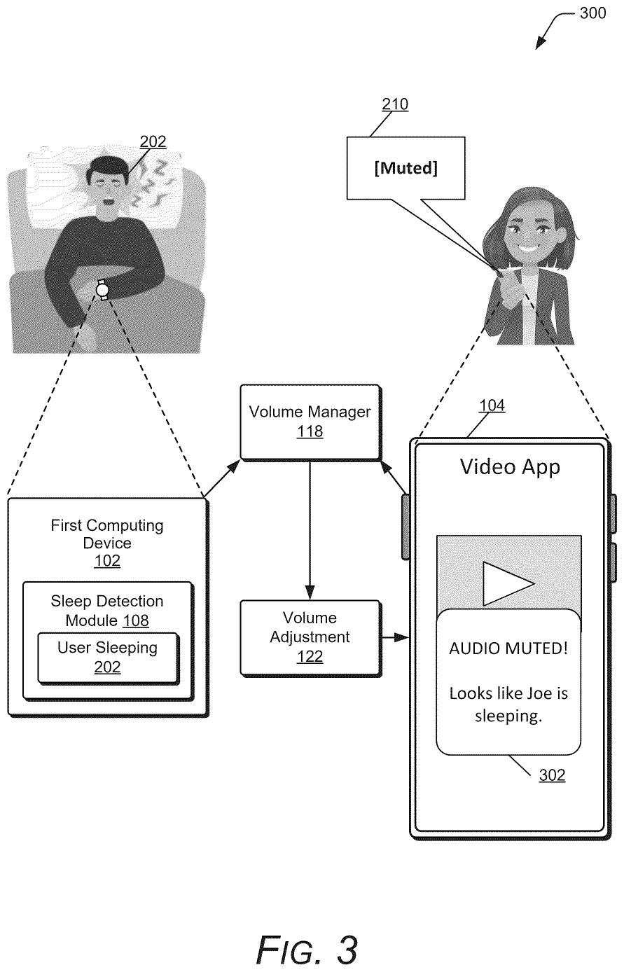

As illustrated in this example, the second computing device 104 includes a speaker system 110 which may be configured to output audio playback 124. Because the first computing device 102 and the second computing device 104 are within the threshold distance 204 of each other, the audio playback 124 may interrupt the user of the first computing device 102, who is sleeping, when the user of the first computing device 102 is sleeping. The volume manager 118 may determine that the media is active on the second computing device based on received data from the second computing device 104 indicating that the speaker system 110 is actively outputting audio. Additionally or alternatively, the volume manager 118 may determine the status 208 of the media 206 based on detecting the audio playback 124 from the second computing device 104. In this example, volume manager 118 detects media audio 210 of a podcast playing on the second computing device 104, which starts off by saying “In today's news . . .” Based on the media audio 210, for instance, the volume manager 118 determines that the status 208 of the media 206 is active, which is used to adjust a volume of the audio playback as described with regard to FIG. 3 below.

FIG. 3 illustrates an example 300 of adjusting volume of audio playback based on a detected user sleeping, including sending a trigger to a second computing device to adjust a volume of audio playback, as described herein. The example 300 is a continuation of the example 200 described with respect to FIG. 2. After determining that the user of the first computing device 102 is sleeping 202, the first computing device 102 and the second computing device 104 are located within a threshold distance 204, and the status 208 of the media 206 on the second computing device 104 is active, the volume manager 118 initiates a volume adjustment 122 on the second computing device 104.

The volume manager 118 may transmit instructions to the second computing device 104 to instruct the second computing device 104 to perform a volume adjustment 122. In this example, the volume adjustment 122 includes muting the speaker system 110 of the second computing device 104. For example, the media audio 210 played from the second computing device 104 is muted. In other example implementations, however, the volume adjustment 122 may involve lowering a volume of the speaker system 110. In implementations involving the volume manager 118 housed internally in the second computing device 104, the volume manager 118 causes the volume adjustment 122 to the second computing device 104.

As illustrated in this example, the volume manager 118 causes display of a message 302 on a display of the second computing device 104 indicating the volume adjustment 122. For example, the message reads “Audio Muted! Looks like Joe is sleeping.” The message 302 for example, may indicate to the user of the second computing device 104 that the audio playback 124 from the second computing device 104 is interrupting the user of the first computing device 102 sleeping.

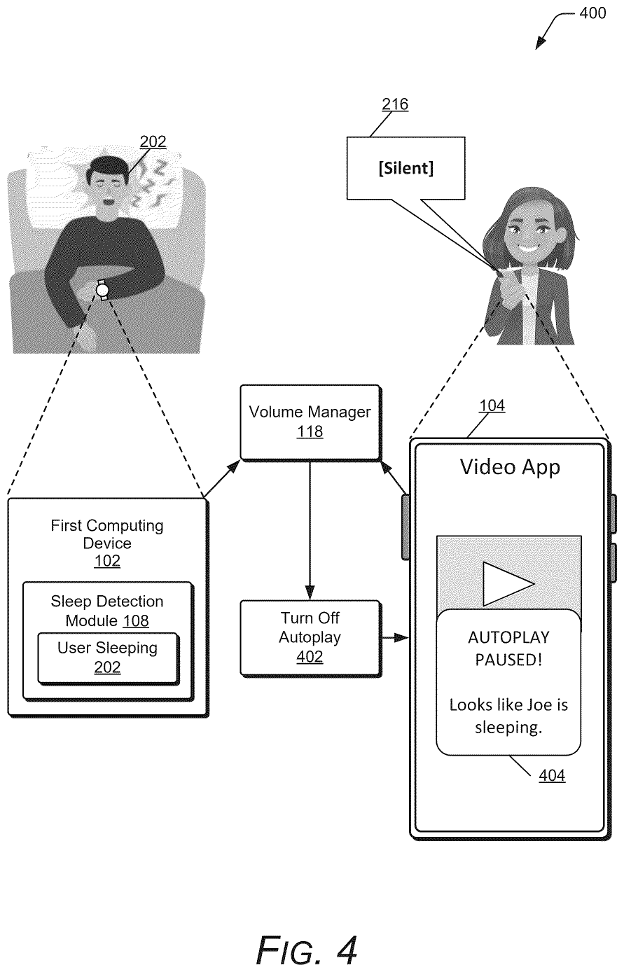

FIG. 4 illustrates an example 400 of adjusting volume of audio playback based on a detected user sleeping, including sending a trigger to a second computing device to turn off autoplay, as described herein. The example 400 is a continuation of the example 200 described with respect to FIG. 2 or the example 300 described with respect to FIG. 3. After determining that the user of the first computing device 102 is sleeping, the first computing device 102 and the second computing device 104 are located within a threshold distance 204, and the status 208 of the media 206 on the second computing device 104 is active, the volume manager 118 turns off autoplay 402 on the second computing device 104.

The volume manager 118 may transmit instructions to the second computing device 104 to pause or end autoplay 402. The autoplay 402, for instance, may be an active feature on the second computing device 104 that involves automatically playing audio and/or video next in a queue on a media app on the second computing device 104. Additionally or alternatively, the autoplay 402 may involve automatically playing advertisements or pop-up videos on websites or social media accessed on the second computing device 104. Although the media initiated by the autoplay 402 on the second computing device 104 may be unintentional, the media is interruptive to the user of the first computing device 102 while sleeping and is therefore turned off by the volume manager 118.

As illustrated in this example, the volume manager 118 causes display of a message 404 on a display of the second computing device 104 indicating the autoplay 402 is paused. For example, the message reads “Autoplay paused! Looks like Joe is sleeping.” The message 302 for example, may indicate to the user of the second computing device 104 that the audio playback 124 from the second computing device 104 is interrupting the user of the first computing device 102 while sleeping. The instructions to turn off the autoplay 402 may be performed separately or in conjunction with the instructions to perform the volume adjustment 122 described with respect to FIG. 3.

FIG. 5 illustrates an example 500 of adjusting volume of audio playback based on a detected user sleeping, including determining whether a user of the first computing device is predicted to be sleeping, as described herein. The example 500 is an alternative of the example 200 described with respect to FIG. 2.

As illustrated in this example, the volume manager 118 uses a sleep detection module 108 to determine that the user of the first computing device 102 is sleeping based on sleep data, which may be collected by the first computing device 102 or received by the first computing device 102. The sleep data, for instance, may be related to environmental data, medical data, and/or behavioral data, which may be collected by or received by the sleep detection module 108. Examples of the environmental data include information related to thermostats, lights, noise sensors, ambient sound, smart beds, cameras, and/or motion sensors. Examples of the medical data include data information related to physical movement, breathing patterns, heart rate, brain activity, thermal patterns, and body temperature. Examples of the behavioral data include information related to pre-set schedules, inferred schedules based on historical data, sleep diaries, phone usage patterns, and calendar routines.

To determine whether the user of the first computing device 102 is sleeping 202 using the sleep data, the sleep detection module 108 of the volume manager 118 may use a machine learning model 502 to determine a sleep prediction 504. The sleep prediction 504 indicates a likelihood that the user of the first computing device 102 is sleeping 202. For example, the sleep prediction 504 may indicate that the user of the first computing device 102 is currently sleeping, plans on sleeping, or typically sleeps at a given time. The machine learning model 502 in this example may be trained on data involving historic examples of user sleep patterns and the sleep data.

In an example implementation, the machine learning model 502 uses the environmental data, which may be data collected from other devices in the user's environment that are connected to the first computing device 102 to determine the sleep prediction 504. For example, based on data indicating that lights in a bedroom associated with the user of the first computing device 102 have been turned off and the user is located in the bedroom, the machine learning model 502 determines that the user of the first computing device 102 is likely sleeping.

In an additional example implementation, the machine learning model 502 uses the medical data, which may be data collected directly by the first computing device 102 from the user, to determine the sleep prediction 504. For example, based on data captured from the first computing device 102, which is a smart watch worn by the user, indicating that the user's heart rate, that the user of the first computing device 102 is likely sleeping, as the user's heart rate has lowered below a threshold level typically associated with sleeping.

In an additional example implementation, the machine learning model 502 uses the behavioral data, which may be collected from accounts associated with the user of the first computing device 102 or stored on the first computing device 102, to determine the sleep prediction 504. For example, calendar data saved to an account associated with the user indicates when the user typically goes to bed. Additionally or alternatively, the machine learning model 502 infers a bedtime for the user based on historic computing device usage patterns.

In some example implementations, the volume manager 118 may also determine that the first computing device 102 and the second computing device 104 are physically within proximity of each other, as discussed in detail with respect to FIG. 2. As illustrated in this example, the volume manager 118 determines that the first computing device 102 and the second computing device 104 are located within the threshold distance 204.

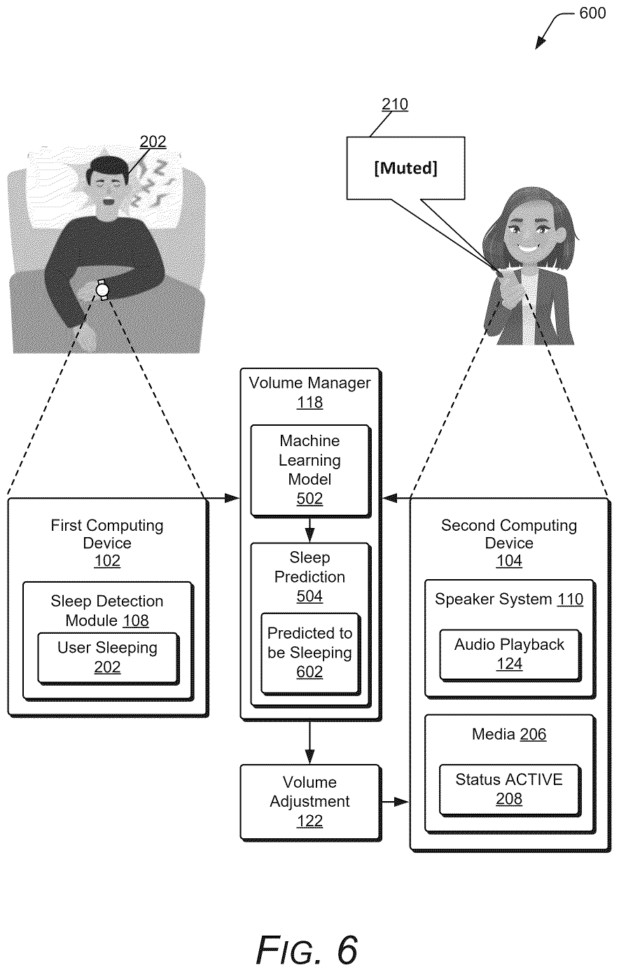

As illustrated in this example, the second computing device 104 includes a speaker system 110 which may be configured to output audio playback 124. Because the first computing device 102 and the second computing device 104 are within the threshold distance 204 of each other, the audio playback 124 may interrupt the user of the first computing device 102 sleeping when media 206 accessed on the second computing device 104 has a status 208 of active and if the user of the first computing device 102 is predicted to be sleeping. The volume manager 118 may determine that the media is active on the second computing device based on received data from the second computing device 104 indicating that the speaker system 110 is actively outputting audio. Additionally or alternatively, the volume manager 118 may determine the status 208 of the media 206 based on detecting the audio playback 124 from the second computing device 104. In this example, volume manager 118 detects media audio 210 of a news broadcast playing on the second computing device 104, which starts off by saying “In today's news . . .” Based on the media audio 210, for instance, the volume manager 118 determines that the status 208 of the media 206 is active, which is used to adjust a volume of the audio playback as described with regard to FIG. 6 below.

FIG. 6 illustrates an example 600 of adjusting volume of audio playback based on a detected user sleeping, including sending a trigger to a second computing device to adjust a volume of audio playback in response to determining that the user of the first computing device is predicted to be sleeping, as described herein. The example 600 is a continuation of the example 500 described with respect to FIG. 5. After determining that the first computing device 102 and the second computing device 104 are located within a threshold distance 204, and the status 208 of the media 206 on the second computing device 104 is active, the volume manager 118 determines the sleep prediction 504.

As illustrated in this example, the volume manager 118 leverages the machine learning model 502 to determine that the user of the first computing device 102 is predicted to be sleeping 602. In response to determining that the user of the first computing device 102 is predicted to be sleeping 602, the volume manager 118 may transmit instructions to the second computing device 104 to perform a volume adjustment 122. In this example, the volume adjustment 122 includes muting the speaker system 110 of the second computing device 104. For example, the media audio 210 played from the second computing device 104 is muted or silenced. In other example implementations, however, the volume adjustment 122 may involve lowering a volume of the speaker system 110. In implementations involving the volume manager 118 housed internally in the second computing device 104, the volume manager 118 causes the volume adjustment 122 to the second computing device 104. Additionally, in some example implementations, the volume manager 118 may cause display of a message on a display of the second computing device 104 indicating the volume adjustment 122 and indicating to the user of the second computing device 104 that the audio playback 124 from the second computing device 104 is interrupting the user of the first computing device 102 from sleeping.

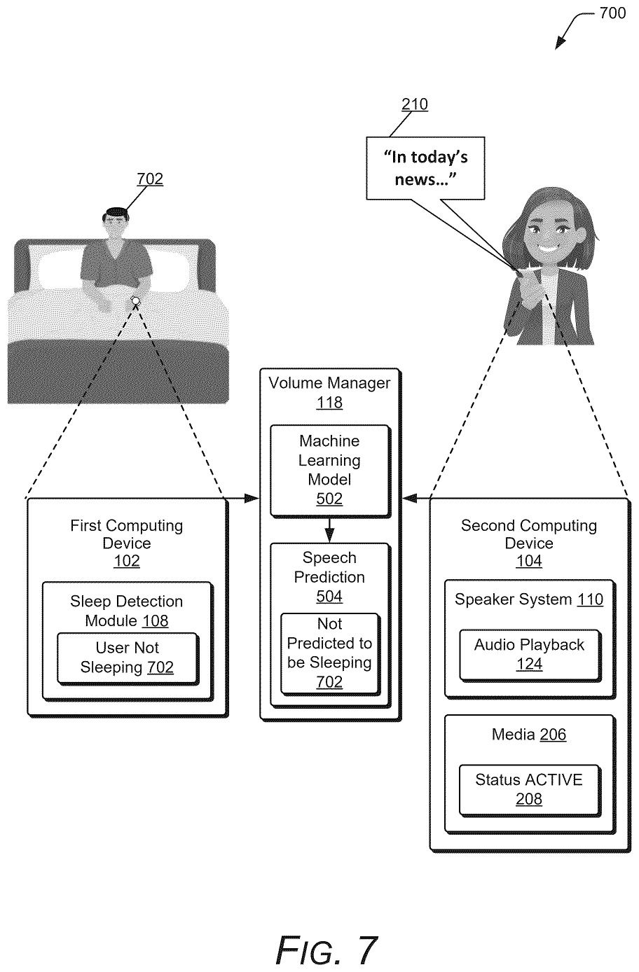

FIG. 7 illustrates an example 700 of adjusting volume of audio playback based on a detected user sleeping, including determining that the user of the first computing device is not predicted to be sleeping, as described herein. The example 700 is an alternative implementation of the example 600 described with respect to FIG. 6. After determining that the first computing device 102 and the second computing device 104 are located within a threshold distance 204 and the status 208 of the media 206 on the second computing device 104 is active, the volume manager 118 determines the sleep prediction 504.

As illustrated in this example, the volume manager 118 leverages the machine learning model 502 to determine that the user of the first computing device 102 is not predicted to be sleeping 702. For example, the machine learning model 502 determines that the user of the first computing device 102 is not currently sleeping based on the sleep data. The machine learning model 502, for instance, analyzes the sleep data, including the environmental data, the medical data, and/or the behavioral data to determine the sleep prediction 504. Therefore, the sleep prediction 504 in this example indicates that the user of the first computing device 102 is not predicted to be sleeping 702. In response, the audio playback 124 on the second computing device 104 continues to play uninterrupted, as a volume adjustment 122 does not occur. The volume manager 118 does, however, continue to monitor for the user of the first computing device 102 sleeping.

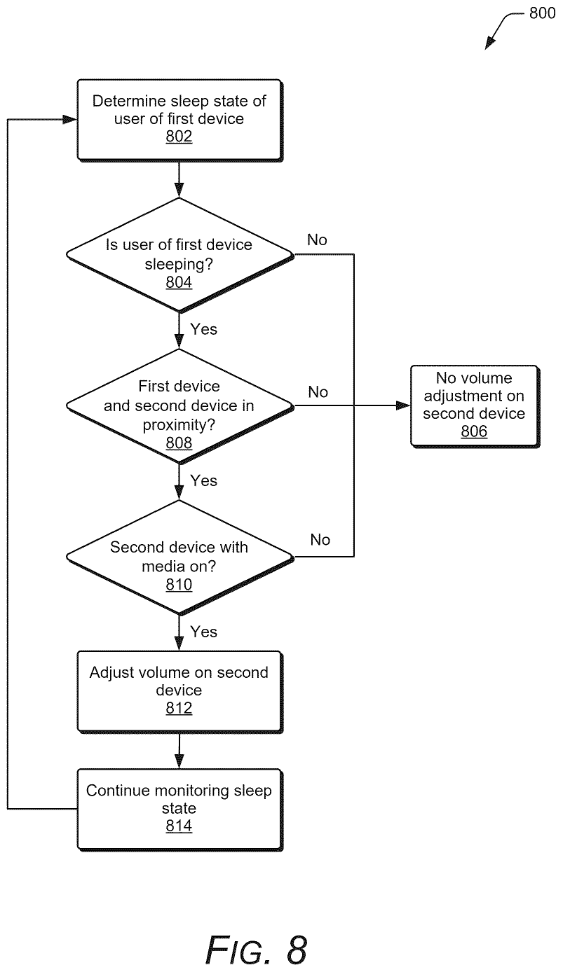

FIG. 8 is a flowchart 800 illustrating an example of adjusting volume of audio playback based on a detected user sleeping in accordance with one or more implementations, as described herein.

At 802, a volume manager 118 determines a sleep state of a user of the first computing device 102. At 804, the volume manager 118 determines whether the user of the first computing device 102 is sleeping. If the user of the first computing device 102 is not determined to be sleeping, the volume manager 118 makes no volume adjustment at 806 and continues to determine the sleep state of the user of the first computing device 102.

At 808, the volume manager 118 monitors whether the first computing device 102 is located within a close proximity of a second computing device 104. For example, the volume manager 118 determines whether the first computing device 102 and the second computing device 104 are located within a threshold distance based on location data, calendar data, or other location-specifying data from the first computing device 102 and the second computing device 104 or associated with the users of the devices. If the second computing device 104 is not co-located with the first computing device 102, the volume manager 118 makes no volume adjustment at 806 and continues to determine the sleep state of the user of the first computing device 102.

At 810, the volume manager 118 monitors whether the second computing device 104 has media playing. For example, the volume manager 118 detects whether the second computing device 104 is playing media that outputs audio playback 124 that interrupts the user of the first computing device 102 from sleeping. If the second computing device 104 does not have media playing, the volume manager 118 makes no volume adjustment at 806 and continues to determine the sleep state of the user of the first computing device 102.

At 812, the volume manager 118 determines a volume adjustment 122 on the second computing device 104. For example, the volume adjustment 122 may involve muting the audio playback 124 at the second computing device 104 while the user of the first computing device 102 is sleeping. Additionally, in some examples the volume manager 118 causes display of a message 302 alerting a user of the second computing device 104 that the user of the first computing device 102 is sleeping.

At 814, the volume manager 118 continues to monitor the sleep state of the user of the first computing device 102. For example, if the user of the first computing device 102 wakes up and is no longer sleeping, the volume manager 118 unmutes the second computing device 104 so that the audio playback 124 is no longer interrupted.

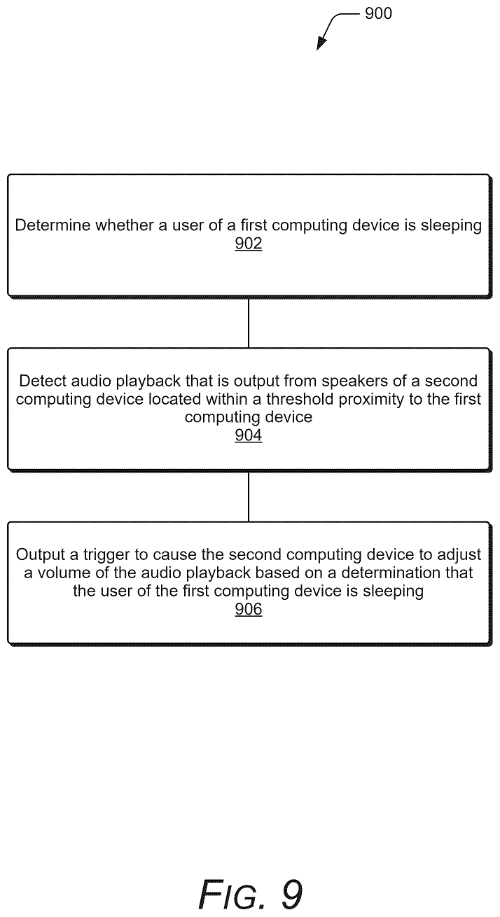

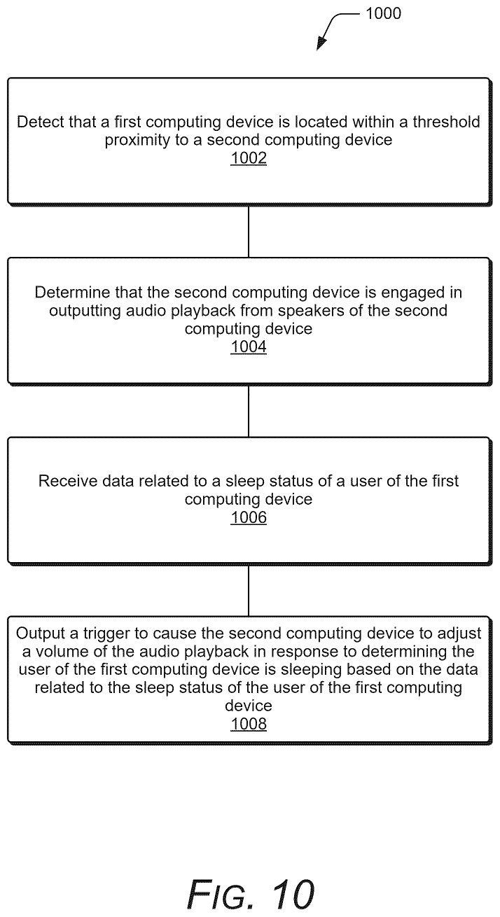

Example methods 900 and 1000 are described with reference to respective FIGS. 9 and 10 in accordance with one or more implementations of adjusting volume of audio playback based on a detected user sleeping, as described herein. Generally, any services, components, modules, managers, controllers, methods, and/or operations described herein can be implemented using software, firmware, hardware (e.g., fixed logic circuitry), manual processing, or any combination thereof. Some operations of the example methods may be described in the general context of executable instructions stored on computer-readable storage memory that is local and/or remote to a computer processing system, and implementations can include software applications, programs, functions, and the like. Alternatively or in addition, any of the functionality described herein can be performed, at least in part, by one or more hardware logic components, such as, and without limitation, Field-programmable Gate Arrays (FPGAs), Application-specific Integrated Circuits (ASICs), Application-specific Standard Products (ASSPs), System-on-a-chip systems (SoCs), Complex Programmable Logic Devices (CPLDs), and the like.

FIG. 9 illustrates example method(s) 900 for adjusting volume of audio playback based on a detected user sleeping. The order in which the method is described is not intended to be construed as a limitation, and any number or combination of the described method operations may be performed in any order to perform a method, or an alternate method.

At 902, it is determined whether a user of a first computing device sleeping For example, the volume manager 118 determines whether a user of the first computing device 102 is sleeping. For example, the first computing device 102 is a wearable device and the volume manager 118 determines whether the user of the first computing device 102 is sleeping based on sensor data collected by the first computing device 102. In some examples, the sensor data includes at least one of movement data, breathing data, heart rate data, brain activity data, or thermal data for the user of the first computing device. Additionally, in some examples, the volume manager 118 determines whether the user of the first computing device is sleeping using a machine learning model 502. For example, the machine learning model 502 determines whether the user of the first computing device 102 is sleeping based on at least one of behavioral information, environmental information, or medical information related to the user of the first computing device. In some examples, the volume manager 118 receives an input indicating whether the user of the first computing device 102 is sleeping.

At 904, audio playback is detected that is output from speakers of a second computing device located within a threshold proximity to the first computing device. For example, the volume manager 118 detects audio playback 124 is output from speakers of a second computing device 104 located within a threshold proximity to the first computing device 102.

At 906, a trigger is sent to the second computing device to adjust a volume of the audio playback based on a determination that the user of the first computing device is sleeping. For example, the volume manager 118 sends a trigger 134 to the second computing device 104 to adjust a volume of the audio playback 124 based on a determination that the user of the first computing device 102 is sleeping. For example, the volume manager 118 lowers the volume of the audio playback 124 on the second computing device 104 in response to determining that the user of the first computing device 102 is sleeping. In some examples, the trigger is configured to instruct the second computing device 104 to turn off auto play on the second computing device 104. Additionally or alternatively, the trigger is configured to cause the second computing device 104 to output an alert that the user of the first computing device 102 is sleeping.

FIG. 10 illustrates example method(s) 1000 for adjusting volume of audio playback based on a detected user sleeping. The order in which the method is described is not intended to be construed as a limitation, and any number or combination of the described method operations may be performed in any order to perform a method, or an alternate method.

At 1002, a first computing device located within a threshold proximity to a second computing device is detected. For example, the volume manager 118 detects that a first computing device 102 is located within a threshold proximity to a second computing device 104. For example, the volume manager 118 determines, based on GPS or UWB data collected from the first computing device 102 and the second computing device 104, that the first computing device 102 is located within the threshold proximity to the second computing device 104. In some examples, the threshold proximity is based on the first computing device 102 and the second computing device 104 being located inside a room or other pre-defined area.

At 1004, it is determined that the second computing device is engaged in outputting audio playback from speakers of the second computing device. For example, the volume manager 118 determines that the second computing device 104 is engaged in outputting audio playback from speakers of the second computing device 104.

At 1006, data related to a sleep status of a user of the first computing device is received. For example, the volume manager 118 receives data related to a sleep status of a user of the first computing device 102. For example, the first computing device 102 is a wearable device and the volume manager 118 determines whether the user of the first computing device 102 is sleeping based on sensor data collected by the first computing device 102. In some examples, the sensor data includes at least one of movement data, breathing data, heart rate data, brain activity data, or thermal data for the user of the first computing device. Additionally, in some examples, the volume manager 118 determines, whether the user of the first computing device is sleeping using a machine learning model 502. For example, the machine learning model 502 determines whether the user of the first computing device 102 is sleeping based on at least one of behavioral information, environmental information, or medical information related to the user of the first computing device. In some examples, the volume manager 118 receives an input indicating whether the user of the first computing device 102 is sleeping.

At 1008, a trigger is output to cause the second computing device to adjust a volume of the audio playback in response to determining the user of the first computing device is sleeping based on the data related to the sleep status of the user of the first computing device. For example, the volume manager 118 outputs a trigger to cause the second computing device to adjust a volume of the audio playback in response to determining the user of the first computing device is sleeping based on the data related to the sleep status of the user of the first computing device. For example, the volume manager 118 lowers the volume of the audio playback 124 on the second computing device 104 in response to determining that the user of the first computing device 102 is sleeping. In some examples, the trigger is configured to instruct the second computing device 104 to turn off auto play on the second computing device 104. Additionally or alternatively, the trigger is configured to cause the second computing device 104 to output an alert that the user of the first computing device 102 is sleeping.

FIG. 11 illustrates various components of an example device 1100, which can implement aspects of the techniques and features for adjusting volume of audio playback based on a detected user sleeping, as described herein. The example device 1100 may be implemented as any of the devices described with reference to the previous FIG. 1-10, such as any type of a wireless device, mobile device, mobile phone, flip phone, client device, companion device, display device, tablet, computing, communication, entertainment, gaming, media playback, and/or any other type of computing, consumer, and/or electronic device. For example, the sleep detection module 108 described with reference to FIGS. 1-10 may be implemented as the example device 1100.

The example device 1100 can include various, different communication devices 1102 that enable wired and/or wireless communication of device data 1104 with other devices. The device data 1104 can include any of the various devices data and content that is generated, processed, determined, received, stored, and/or communicated from one computing device to another. Generally, the device data 1104 can include any form of audio, video, image, graphics, and/or electronic data that is generated by applications executing on a device. The communication devices 1102 can also include transceivers for cellular phone communication and/or for any type of network data communication.

The example device 1100 can also include various, different types of data input/output (I/O) interfaces 1106, such as data network interfaces that provide connection and/or communication links between the devices, data networks, and other devices. The data I/O interfaces 1106 may be used to couple the device to any type of components, peripherals, and/or accessory devices, such as a computer input device that may be integrated with the example device 1100. The I/O interfaces 1106 may also include data input ports via which any type of data, information, media content, communications, messages, and/or inputs may be received, such as user inputs to the device, as well as any type of audio, video, image, graphics, and/or electronic data received from any content and/or data source.

The example device 1100 includes a processor system 1108 of one or more processors (e.g., any of microprocessors, controllers, and the like) and/or a processor and memory system implemented as a system-on-chip (SoC) that processes computer-executable instructions. The processor system 1108 may be implemented at least partially in computer hardware, which can include components of an integrated circuit or on-chip system, an application-specific integrated circuit (ASIC), a field-programmable gate array (FPGA), a complex programmable logic device (CPLD), and other implementations in silicon and/or other hardware. Alternatively, or in addition, the device may be implemented with any one or combination of software, hardware, firmware, or fixed logic circuitry that may be implemented in connection with processing and control circuits, which are generally identified at 1110. The example device 1100 may also include any type of a system bus or other data and command transfer system that couples the various components within the device. A system bus can include any one or combination of different bus structures and architectures, as well as control and data lines.

The example device 1100 also includes memory and/or memory devices 1112 (e.g., computer-readable storage memory) that enable data storage, such as data storage devices implemented in hardware which may be accessed by a computing device, and that provide persistent storage of data and executable instructions (e.g., software applications, programs, functions, and the like). Examples of the memory devices 1112 include volatile memory and non-volatile memory, fixed and removable media devices, and any suitable memory device or electronic data storage that maintains data for computing device access. The memory devices 1112 can include various implementations of random-access memory (RAM), read-only memory (ROM), flash memory, and other types of storage media in various memory device configurations. The example device 1100 may also include a mass storage media device.

The memory devices 1112 (e.g., as computer-readable storage memory) provide data storage mechanisms, such as to store the device data 1104, other types of information and/or electronic data, and various device applications 1114 (e.g., software applications and/or modules). For example, an operating system 1116 may be maintained as software instructions with a memory device 1112 and executed by the processor system 1108 as a software application. The device applications 1114 may also include a device manager, such as any form of a control application, software application, signal-processing and control module, code that is specific to a particular device, a hardware abstraction layer for a particular device, and so on.

In this example, the device 1100 includes a volume manager 1118 that implements various aspects of the described features and techniques described herein. The volume manager 1118 may be implemented with hardware components and/or in software as one of the device applications 1114, such as when the example device 1100 is implemented as the sleep detection module 108 described with reference to FIGS. 1-10. An example of the volume manager 1118 is the Communication network 106 implemented by the sleep detection module 108, such as a software application and/or as hardware components in the mobile device. In implementations, the volume manager 1118 may include independent processing, memory, and logic components as a computing and/or electronic device integrated with the example device 1100.

The example device 1100 can also include a microphone 1120 (e.g., to capture an audio recording) and/or camera devices 1122, as well as device sensors 1124, such as may be implemented as components of an inertial measurement unit (IMU). The device sensors 1124 may be implemented with various sensors, such as a gyroscope, an accelerometer, and/or other types of motion sensors to sense motion of the device. The device sensors 1124 can generate sensor data vectors having three-dimensional parameters (e.g., rotational vectors in x, y, and z-axis coordinates) indicating location, position, acceleration, rotational speed, and/or orientation of the device. The example device 1100 can also include one or more power sources 1126, such as when the device is implemented as a wireless device and/or a mobile device. The power sources may include a charging and/or power system, and may be implemented as a flexible strip battery, a rechargeable battery, a charged super-capacitor, and/or any other type of active or passive power source.

The example device 1100 can also include an audio and/or video processing system 1128 that generates audio data for an audio system 1130 and/or generates display data for a display system 1132. The audio system and/or the display system may include any types of devices or modules that generate, process, display, and/or otherwise render audio, video, display, and/or image data. Display data and audio signals may be communicated to an audio component and/or to a display component via any type of audio and/or video connection or data link. In implementations, the audio system and/or the display system are integrated components of the example device 1100. Alternatively, the audio system and/or the display system are external, peripheral components to the example device.

Although implementations for adjusting volume of audio playback based on a detected user sleeping have been described in language specific to features and/or methods, the appended claims are not necessarily limited to the specific features or methods described. Rather, the specific features and methods are disclosed as example implementations for adjusting volume of audio playback based on a detected user sleeping, and other equivalent features and methods are intended to be within the scope of the appended claims. Further, various different examples are described, and it is to be appreciated that each described example may be implemented independently or in connection with one or more other described examples. Additional aspects of the techniques, features, and/or methods discussed herein relate to one or more of the following:

In some aspects, the techniques described herein relate to a first computing device, including: at least one memory, and at least one processor coupled with the at least one memory and configured to cause the first computing device to: determine whether a user of the first computing device is sleeping, detect audio playback that is output from speakers of a second computing device located within a threshold proximity to the first computing device, and output a trigger to cause the second computing device to adjust a volume of the audio playback based on a determination that the user of the first computing device is sleeping.

In some aspects, the techniques described herein relate to a first computing device, wherein the at least one processor is further configured to cause the first computing device to instruct the second computing device to lower the volume of the audio playback on the second computing device in response to determining that the user of the first computing device is sleeping.

In some aspects, the techniques described herein relate to a first computing device, wherein the trigger is configured to instruct the second computing device to turn off auto play on the second computing device.

In some aspects, the techniques described herein relate to a first computing device, wherein the trigger is configured to cause the second computing device to output an alert that the user of the first computing device is sleeping.

In some aspects, the techniques described herein relate to a first computing device, wherein the first computing device is a wearable device and the at least one processor is further configured to determine whether the user of the first computing device is sleeping based on sensor data collected by the first computing device.

In some aspects, the techniques described herein relate to a first computing device, wherein the sensor data includes at least one of movement data, breathing data, heart rate data, brain activity data, or thermal data for the user of the first computing device.

In some aspects, the techniques described herein relate to a first computing device, wherein the at least one processor is further configured to cause the first computing device to determine, using a machine learning model, whether the user of the first computing device is sleeping.

In some aspects, the techniques described herein relate to a first computing device, wherein the machine learning model determines whether the user of the first computing device is sleeping based on at least one of behavioral information, environmental information, or medical information related to the user of the first computing device.

In some aspects, the techniques described herein relate to a first computing device, wherein the at least one processor is further configured to receive an input indicating whether the user of the first computing device is sleeping.

In some aspects, the techniques described herein relate to a second computing device, including: at least one memory, and at least one processor coupled with the at least one memory and configured to cause the second computing device to: determine whether a user of a first computing device is sleeping, detect audio playback that is output from speakers of the second computing device located within a threshold proximity to the first computing device, and output a trigger to cause the second computing device to adjust a volume of the audio playback based on a determination that the user of the first computing device is sleeping.

In some aspects, the techniques described herein relate to a second computing device, wherein the at least one processor is further configured to cause the second computing device to lower the volume of the audio playback on the second computing device in response to determining that the user of the first computing device is sleeping.

In some aspects, the techniques described herein relate to a second computing device, wherein the trigger is configured to cause the second computing device to output an alert that the user of the first computing device is sleeping.

In some aspects, the techniques described herein relate to a second computing device, wherein the first computing device is a wearable device and the at least one processor is further configured to determine whether the user of the first computing device is sleeping based on sensor data received from the first computing device.

In some aspects, the techniques described herein relate to a second computing device, wherein the sensor data includes at least one of movement data, breathing data, heart rate data, brain activity data, or thermal data for the user of the first computing device.

In some aspects, the techniques described herein relate to a second computing device, wherein the at least one processor is further configured to cause the second computing device to lower the volume of the audio playback on the second computing device in response to determining, using a machine learning model, that the user of the first computing device is sleeping.

In some aspects, the techniques described herein relate to a second computing device, wherein the machine learning model determines whether the user of the first computing device is sleeping based on at least one of behavioral information, environmental information, or medical information related to the user of the first computing device.

In some aspects, the techniques described herein relate to a method including: detecting that a first computing device is located within a threshold proximity to a second computing device, determining that the second computing device is engaged in outputting audio playback from speakers of the second computing device, receiving data related to a sleep status of a user of the first computing device, and outputting a trigger to cause the second computing device to adjust a volume of the audio playback in response to determining the user of the first computing device is sleeping based on the data related to the sleep status of the user of the first computing device.

In some aspects, the techniques described herein relate to a method, further including lowering the volume of the audio playback in response to determining that the user of the first computing device is sleeping.

In some aspects, the techniques described herein relate to a method, further including turning off auto play on the second computing device.

In some aspects, the techniques described herein relate to a method, further including lowering the volume of the audio playback in response to determining, using a machine learning model, that the user of the first computing device is sleeping.

1. A first computing device, comprising:
at least one memory; and
at least one processor coupled with the at least one memory and configured to cause the first computing device to:
determine whether a user of the first computing device is sleeping;
detect audio playback that is output from speakers of a second computing device located within a threshold proximity to the first computing device; and
output a trigger to cause the second computing device to adjust a volume of the audio playback based on a determination that the user of the first computing device is sleeping.

2. The first computing device of claim 1, wherein the at least one processor is further configured to cause the first computing device to instruct the second computing device to lower the volume of the audio playback on the second computing device in response to determining that the user of the first computing device is sleeping.

3. The first computing device of claim 1, wherein the trigger is configured to instruct the second computing device to turn off auto play on the second computing device.

4. The first computing device of claim 1, wherein the trigger is configured to cause the second computing device to output an alert that the user of the first computing device is sleeping.

5. The first computing device of claim 1, wherein the first computing device is a wearable device and the at least one processor is further configured to determine whether the user of the first computing device is sleeping based on sensor data collected by the first computing device.

6. The first computing device of claim 5, wherein the sensor data includes at least one of movement data, breathing data, heart rate data, brain activity data, or thermal data for the user of the first computing device.

7. The first computing device of claim 1, wherein the at least one processor is further configured to cause the first computing device to determine, using a machine learning model, whether the user of the first computing device is sleeping.

8. The first computing device of claim 7, wherein the machine learning model determines whether the user of the first computing device is sleeping based on at least one of behavioral information, environmental information, or medical information related to the user of the first computing device.

9. The first computing device of claim 1, wherein the at least one processor is further configured to receive an input indicating whether the user of the first computing device is sleeping.

10. A second computing device, comprising:
at least one memory; and
at least one processor coupled with the at least one memory and configured to cause the second computing device to:
determine whether a user of a first computing device is sleeping;
detect audio playback that is output from speakers of the second computing device located within a threshold proximity to the first computing device; and
output a trigger to cause the second computing device to adjust a volume of the audio playback based on a determination that the user of the first computing device is sleeping.

11. The second computing device of claim 10, wherein the at least one processor is further configured to cause the second computing device to lower the volume of the audio playback on the second computing device in response to determining that the user of the first computing device is sleeping.

12. The second computing device of claim 10, wherein the trigger is configured to cause the second computing device to output an alert that the user of the first computing device is sleeping.

13. The second computing device of claim 10, wherein the first computing device is a wearable device and the at least one processor is further configured to determine whether the user of the first computing device is sleeping based on sensor data received from the first computing device.

14. The second computing device of claim 13, wherein the sensor data includes at least one of movement data, breathing data, heart rate data, brain activity data, or thermal data for the user of the first computing device.

15. The second computing device of claim 10, wherein the at least one processor is further configured to cause the second computing device to lower the volume of the audio playback on the second computing device in response to determining, using a machine learning model, that the user of the first computing device is sleeping.

16. The second computing device of claim 15, wherein the machine learning model determines whether the user of the first computing device is sleeping based on at least one of behavioral information, environmental information, or medical information related to the user of the first computing device.

17. A method comprising:
detecting that a first computing device is located within a threshold proximity to a second computing device;
determining that the second computing device is engaged in outputting audio playback from speakers of the second computing device;
receiving data related to a sleep status of a user of the first computing device; and
outputting a trigger to cause the second computing device to adjust a volume of the audio playback in response to determining the user of the first computing device is sleeping based on the data related to the sleep status of the user of the first computing device.

18. The method of claim 17, further comprising lowering the volume of the audio playback in response to determining that the user of the first computing device is sleeping.

19. The method of claim 17, further comprising turning off auto play on the second computing device.

20. The method of claim 17, further comprising lowering the volume of the audio playback in response to determining, using a machine learning model, that the user of the first computing device is sleeping.
